(19) United States
(12) Patent Application Publication
(10) Pub. No.: US 2022/0239251 A1
(43) Pub. Date: Jul. 28, 2022

(54) SYSTEM FOR PROVIDING THE ENERGY FROM A SINGLE CONTIGUOUS SOLAR ENERGY STRUCTURE TO AT LEAST TWO DIFFERENT METERS

(71) Applicant: STRATEGIC SOLAR ENERGY, LLC, Chandler, AZ (US)

(72) Inventor: Thomas Headley, Chandler, AZ (US)

(73) Assignee: STRATEGIC SOLAR ENERGY, LLC, Chandler, AZ (US)

(21) Appl. No.: 17/580,956

(22) Filed: Jan. 21, 2022

Related U.S. Application Data
(60) Provisional application No. 63/140,467, filed on Jan. 22, 2021.

(51) Int. Cl. H02S 40/32; G01R 22/06; H02S 40/38; B60L 53/51

(52) U.S. Cl. CPC H02S 40/32; B60L 53/51; H02S 40/38; G01R 22/061

(57) ABSTRACT

In accordance with an example embodiment, a solar energy system comprises: a solar energy structure comprising photovoltaic solar panels contiguously covering an area; a first inverter configured to receive power from a first string of photovoltaic solar panels, wherein the first inverter is configured to provide the power received at the first inverter to a first meter; and a second inverter configured to receive power from a second string of photovoltaic solar panels, wherein the second inverter is configured to provide the power received at the second inverter to a second meter.

### RELATED APPLICATION

The present Application claims the benefit of priority to U.S. Provisional Application No. 63/140,467 filed on Jan. 22, 2021, entitled “System for Providing the Energy from a Single Contiguous Solar Energy Structure to at Least Two Different Meters”, the entirety of which is incorporated herein by reference.

### TECHNICAL FIELD

The present disclosure relates to the collection and use of solar energy and, in particular, to the distribution of solar energy from a single contiguous solar energy structure to two or more customers.

### BACKGROUND

Photovoltaic solar energy installations consume land. Once the solar panels have been installed on a parcel of land, the land is of little or no use for anything else unless the solar panels are raised in the air creating shade, shelter to protect assets, (e.g. equipment, personnel, crops, etc.) providing a useable environment under the structure. People are beginning to understand the environmental impact of such practices and are looking for ways to cover more land that is already being used. A problem emerges from building these structures in that the structure can only be as big as the energy appetite of the entity it serves. There exists a need for greater flexibility in photovoltaic solar energy installations associated with specific entities.

### SUMMARY

In accordance with an example embodiment, a solar energy system comprises: a solar energy structure comprising photovoltaic solar panels contiguously covering an area; a first inverter configured to receive power from a first string of photovoltaic solar panels, wherein the first inverter is configured to provide the power received at the first inverter to a first meter; and a second inverter configured to receive power from a second string of photovoltaic solar panels, wherein the second inverter is configured to provide the power received at the second inverter to a second meter.

In accordance with another example embodiment, a solar energy system comprises: a solar energy structure comprising photovoltaic solar panels contiguously covering an area and at least two inverters, wherein the at least two inverters include a first inverter and a second inverter; wherein each of the at least two inverters is configured to respectively route energy to the distribution panel, and wherein the energy distribution panel is configured to switch the energy from the first inverter to a first meter of the plurality of meters, and to switch the energy from the second inverter to the first meter or to a second meter of the plurality of meters.

In accordance with another example embodiment, a method of collecting solar energy comprises: contiguously covering an area with a plurality of photovoltaic solar panels; providing energy from a first inverter associated with a first string of photovoltaic solar panels, from among the plurality of photovoltaic solar panels, to a first meter; and providing the energy from a different inverter associated with a second string of photovoltaic solar panels, from among the plurality of photovoltaic solar panels and different from the first string of photovoltaic solar panels, to a different meter.

In accordance with another example embodiment, a method of collecting solar energy comprises: contiguously covering an area with a plurality of photovoltaic solar panels; providing energy from a first inverter associated with a first string of photovoltaic solar panels, from among the plurality of photovoltaic solar panels, to a first meter; and providing energy from a subset of the plurality of solar panels to an electric vehicle charging station as direct current.

In accordance with another example embodiment, a method of collecting solar energy comprises: contiguously covering an area with a plurality of photovoltaic solar panels; providing energy from a first inverter associated with a first string of photovoltaic solar panels, from among the plurality of photovoltaic solar panels, to a first meter; and providing energy from a subset of the plurality of solar panels to an energy storage device as direct current.

### BRIEF DESCRIPTION OF THE FIGURES

A more complete understanding of exemplary embodiments of the present disclosure can be derived by referring to the detailed description and claims when considered in connection with the following illustrative figures.

FIG. 1 illustrates a standard single user contiguous photovoltaic solar energy structure.

FIG. 2 illustrates an example single line drawing of the output from a contiguous photovoltaic solar energy structure being directed to a single customer according to the standard of the industry.

FIG. 3 illustrates a single line drawing of the output from a contiguous photovoltaic solar energy structure being directed to multiple customers according to exemplary embodiments of the disclosure.

FIG. 4 illustrates a single line drawing of the output from a contiguous photovoltaic solar energy structure being directed partially to an EV charging station and partially to a separate user according to an exemplary embodiment of the disclosure.

FIG. 5 illustrates a single line drawing of the output from a contiguous photovoltaic solar energy structure being directed partially to two users and partially to a battery for later use by a user according to an exemplary embodiment of the disclosure.

FIG. 6 illustrates a single line drawing of the output from a contiguous solar energy structure being directed to multiple customers through an energy distribution panel according to an exemplary embodiment of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

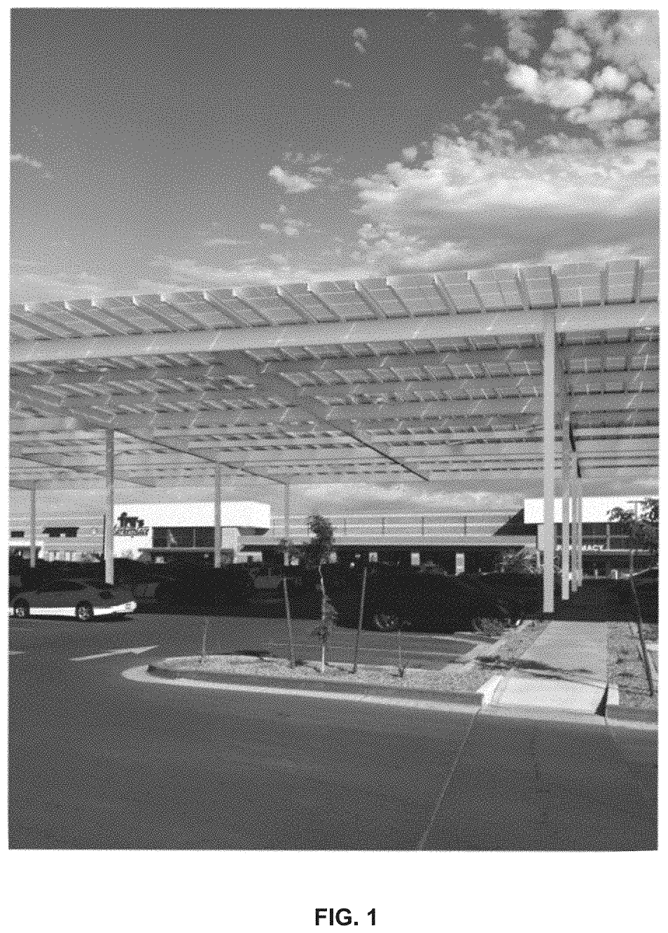

The present disclosure relates to generation and distribution of photovoltaic solar energy that address the shortcomings described above in a way that allows multiple users to use the energy created from a single, contiguous photovoltaic solar energy structure. A typical contiguous photovoltaic solar energy collection system using current technology is shown in FIG. 1. Such a system may comprise a structure supporting photovoltaic solar panels over an area in a contiguous way. The solar energy structure is configured to have two or more inverters. Stated another way, such large contiguous photovoltaic solar energy power generation structures typically require multiple inverters, where one set of solar panels on the structure feed to a first inverter, a different set of solar panels feed to a second inverter, etc.

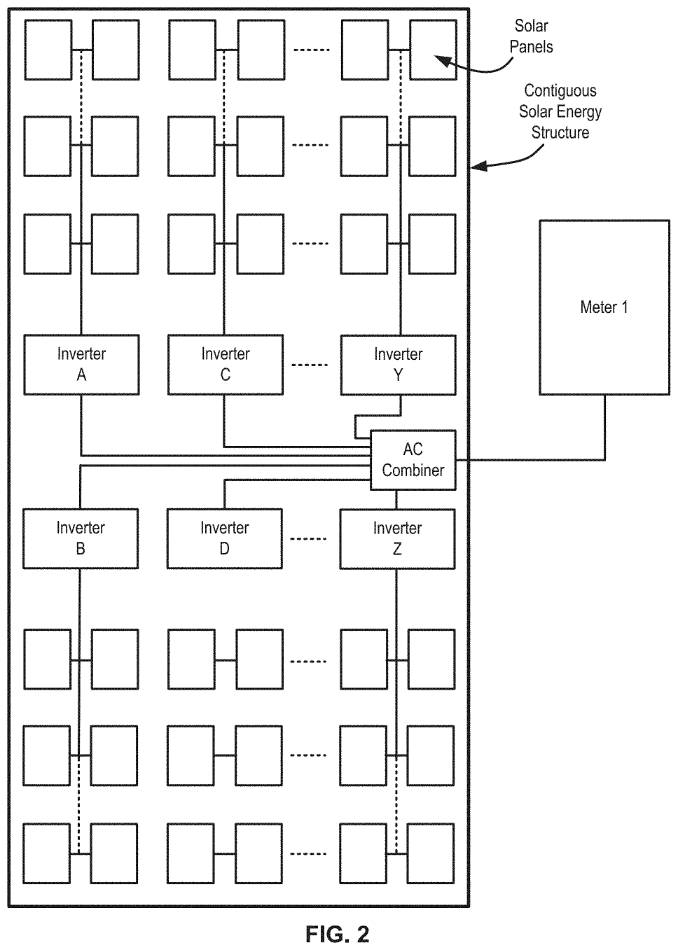

With reference now to FIG. 2, a typical system is illustrated, comprising a contiguous photovoltaic solar energy structure. The contiguous photovoltaic solar energy structure comprises a plurality of solar panels. A first group of solar panels are electrically connected to a first inverter (e.g., inverter A), a second group of solar panels are electrically connected to a second inverter (e.g., inverter B), and so forth for inverters C-Z, with any suitable number of solar panels connected to each inverter, different numbers of solar panels connected to each inverter according to the capacity of the inverter, and any suitable number of inverters. In this example, the inverters A-Z are each electrically connected to an AC combiner. In the industry standard, the AC combiner is configured to provide energy generated from the photovoltaic solar energy collection system (e.g., the inputs from two or more strings of solar panels) to a single meter of a single customer. Systems are built like this, with a one-to-one correlation between the contiguous photovoltaic solar energy generation system and meter for a number of reasons: the structure covers land owned by the customer, the structure is often paid for by the customer, if the structure is associated with power rebates, those rebates typically go to the customer by meter number, the structure typically provides the customer with the energy it puts out, and the structure generally provides shade to clients of the customer. Such a system may provide about 200,000 Watts to over 2,000,000 Watts of solar power to a single customer's meter.

Of course, photovoltaic solar energy is a very important component in the effort to generate clean power for commercial uses, and improvements in the efficiency of photovoltaic panels are all to be celebrated. However, these great improvements have created a problem in the typical solar energy structure one-to-one correlation described above.

As an example of these improvements, in the last ten years, manufacturers of solar panels have increased the solar energy output from the same sized solar panel from about 280 Watts to about 450 Watts. Assuming a single customer's energy needs remained constant, these improvements reduce the size of the solar structure that a single customer can utilize to about 60% of what it was ten years ago. In one example, a customer that uses about 800,000 Watts of energy might have had need for a single structure covering about 85,000 sq. ft. ten years ago, but now that customer only has need for a single structure covering about 53,000 sq. ft. From one perspective, that reduction in the size of the structure might be viewed favorably because it would be seen as reducing the cost of the structure. However, if the photovoltaic structure is set up to provide shade, shelter to protect assets, (e.g. equipment, personnel, crops, etc.) to the entity's customers, an unsatisfactory consequence is that the quantity of shade that could be provided by the structure is significantly reduced.

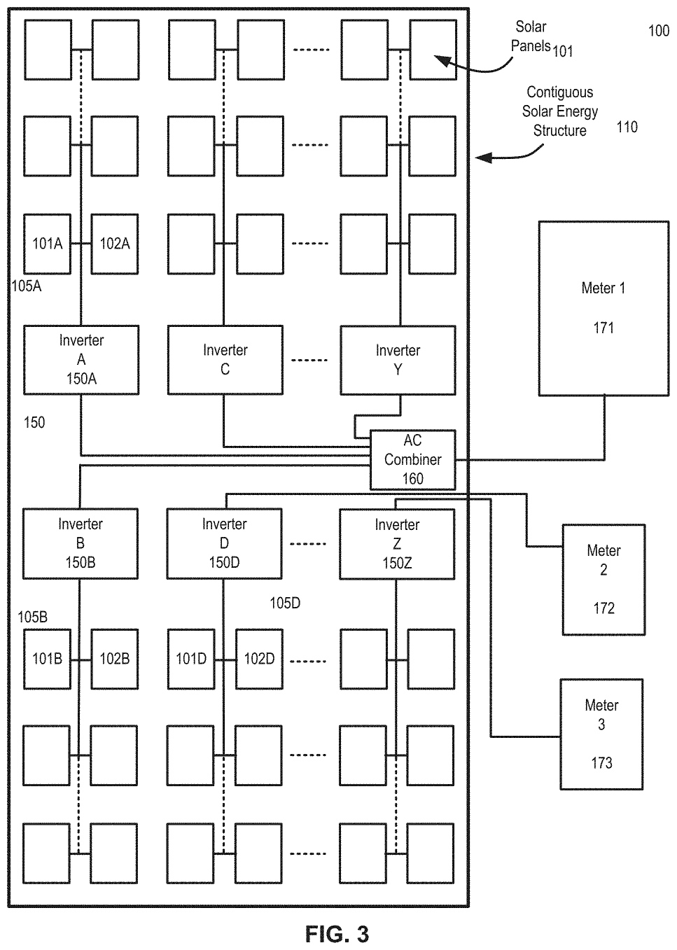

With reference now to FIG. 3, in accordance with an example embodiment, a photovoltaic solar energy generation system 100 comprises a photovoltaic solar energy structure 110 and inverters 150. The solar energy structure 110 may comprise a support structure and solar panels 101. For example, the support structure may comprise structural members configured to support the solar panels 101 at a height above a surface or over an area. In an example embodiment, the support structure comprises metal columns supporting a configuration of beams and purlins for supporting the solar panels 101. In an example embodiment, the support structure is a contiguous structure.

In an example embodiment, the photovoltaic solar energy structure 110 covers a parking lot, a rooftop, a building, a gathering place, a RV park or parking place, a semitrailer parking place or loading place, a cool zone for people protection, an area of ground, an agricultural area or a park area. Moreover, the photovoltaic solar energy structure 110 may contiguously cover any suitable area or several areas. In an example embodiment, the word ‘contiguously’ as used herein means essentially contiguously, such that there can be missing solar panels, gaps between solar panels, and other spaces without solar panel covering, but nonetheless the structure supports a plurality of solar panels with significant solar panel coverage over the area of the structure. For example, the percentage of the area under the structure that is covered by solar panels may be 60%, more preferably 75%, more preferably 95%, and more preferably 100%.

In an example embodiment, the solar panels 101 are monocrystalline solar panels, polycrystalline or thin film solar panels, and/or the like. Moreover, the solar panels 101 may be any suitable photovoltaic panel. The solar panels 101 may be attached to the support structure using screws, welding, clamps, bolts, or any suitable method of attachment.

In an example embodiment, the inverters 150 may comprise string inverters, micro inverters, and/or the like. Moreover, the inverters 150 may be any device that is configured to invert the energy generated by the solar panels associated with that inverter from direct current (DC) to alternating current (AC).

The inverters 150 may be connected to one or more solar panels 101. In particular, in an example embodiment, the photovoltaic solar energy generation system 100 comprises at least a first inverter 150A and a second inverter 150D. As illustrated in FIG. 3, the photovoltaic solar energy generation system 100 may further comprise any suitable number of inverters A-Z. In an example embodiment, the first inverter 150A, is associated with the photovoltaic solar energy structure 110. More specifically, the first inverter 150A is configured to receive power from one or more solar panels in a first subset of solar panels. For example, the first inverter 150A may be configured to receive power from solar panel 101A and 102A in a first subset of solar panels 105A. The first subset of solar panels 105A may have any suitable number of solar panels 101 consistent with the rated capacity of the first inverter 150A.

In an example embodiment, the second inverter 150D, is associated with the photovoltaic solar energy structure 110. More specifically, the second inverter 150D is configured to receive power from one or more solar panels in a second subset of solar panels. For example, the second inverter 150D may be configured to receive power from solar panel 101D and 102D in a second subset of solar panels 105D. The second subset of solar panels 105D may have any suitable number of solar panels consistent with the rated capacity of the second inverter 150D, which need not be the same as the first inverter 150A. Similarly, each inverter A-Z may be configured to receive power from a corresponding subset of solar panels.

In an example embodiment, the first inverter 150A is configured to send energy to a first meter 171 and the second inverter 150D is configured to send energy to a second meter 172. Moreover, a third inverter 150Z may be configured to send energy to a third meter 173. In the illustrated example embodiment, the second inverter 150D sends power to the second meter 172 in a one-to-one arrangement, without combining power from any other inverter(s). Similarly, the third inverter 150Z sends power to the third meter 173 in a one-to-one arrangement, without combining power from any other inverter(s).

However, in an example embodiment, the first inverter 150A may send power to the first meter 171 in a many-to-one arrangement, combining power from other inverters. In an example embodiment, the photovoltaic solar energy generation system 100 comprises an AC combiner 160. Moreover, the AC combiner 160 may be any device that combines power from two or more strings of solar panels 101. The AC combiner 160 may be configured to receive power from the first inverter 150A. In one example embodiment, the AC combiner 160 may further receive power from additional inverters, such as, for example inverter 150B, and/or other inverters (e.g. C and Y). The AC combiner 160 may combine the power from two or more inverters and provide that power to the first customer's meter 171. Although shown here in this specific arrangement, it is noted that each inverter in the photovoltaic solar energy generation system 100 may have a one-to-one arrangement, or other many-to-one arrangements may suitably be formed. In an example embodiment, a single entity may have more than one meter.

Stated another way, the solar panels 101 are divided according to the inverters 150 that they feed and the output of those inverters 150 are correspondingly provided to different customer's meters, or the output of some of those inverters may be combined and provided to a meter while the output of other inverters is combined and provided to other meters and/or is provided correspondingly to different meters.

In an example embodiment, the photovoltaic solar energy generation system 100 is thus configured to distribute the energy produced in this manner in order to facilitate the building of a photovoltaic solar energy shade structure that exceeds the energy needs of the previous single customer and, in turn, allows the construction of a larger structure which provides more shade. Where, without this configuration, all the power from all the solar panels is provided to a single customer, the structure would need to be designed to be smaller and will therefore produce relatively less shade than one with power distribution as described herein. The shade may benefit the first user (or the first user's visitors, customers, employees, etc.) at meter 171 or may benefit multiple users (e.g., users at meters 172, 173).

In an example embodiment, the same size of inverter does not need to be used for all customers. In one preferred example, some customers might use 20 kWh inverters, some 40 kWh inverters and some 100 kWh inverters as long as the total Wattage of the inverters adds up to the size of the photovoltaic solar structure. In this way, the energy put out by the single structure can be customized for the situation as required.

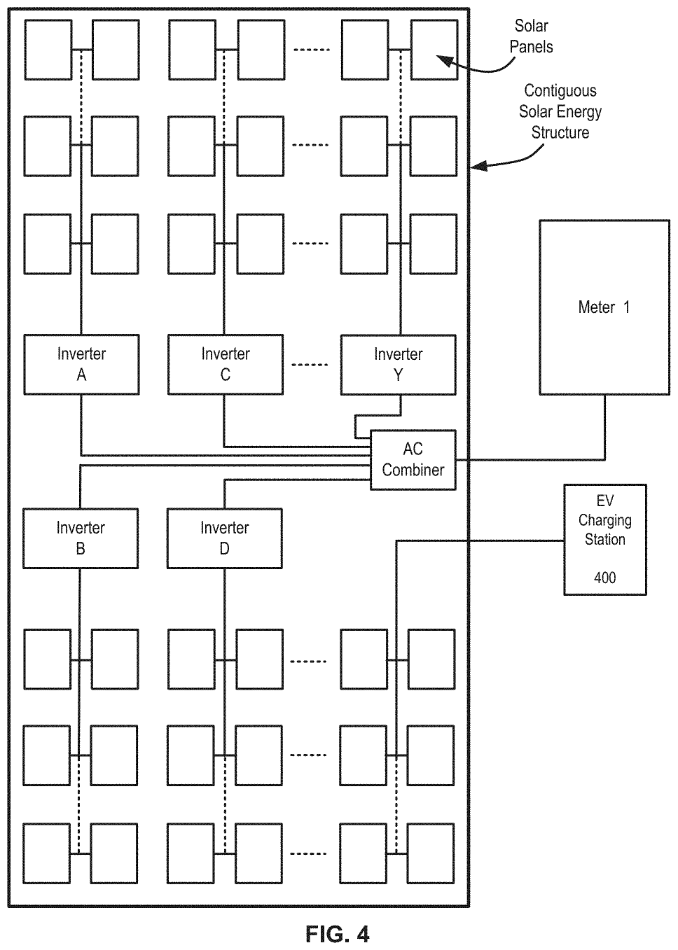

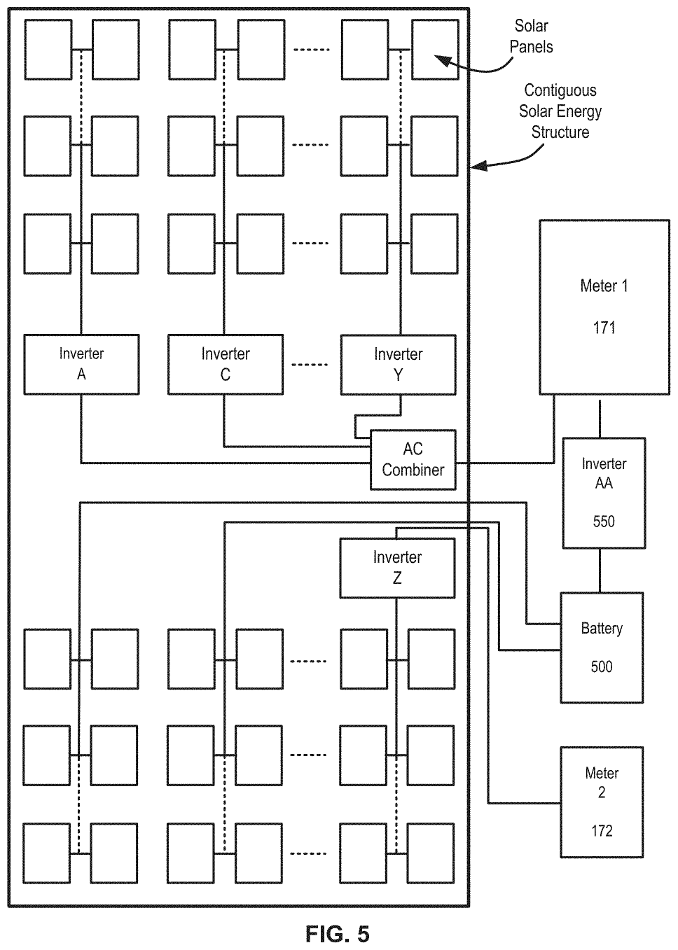

In one preferred example, sometimes an inverter is not used at all and some of the energy is provided in direct current to a user of direct current such as electric vehicle (EV) charging stations 400 (see FIG. 4) and at least one energy storage device (e.g., a battery, a supercapacitor, or the like) 500 (see FIG. 5). With further reference to FIG. 4, the EV charging station 400 may be configured to receive power from one or more solar panels, without an inverter interposed between the solar panels and the EV charging station 400. Thus, in an example embodiment, the electric vehicle charging system 400 or energy storage system may receive power from a subsection of the plurality of solar panels as direct current, may receive power from one or more inverters, or may receive power in any appropriate manner. The EV charging station 400 may be configured to charge plug-in electric vehicles, hybrid electric vehicles, and/or the like. In an example embodiment, the EV charging station 400 is a level 1, level 2, level 3, or other type charging station, however the EV charging station 400 can be any suitable type of EV charging station.

With further reference to FIG. 5, the battery 500 may be configured to receive power from one or more solar panels, without an inverter interposed between the solar panels and the battery. Moreover, the battery 500 may be configured to store the power received. The battery 500 may further be configured to provide the stored power to an inverter AA 550. Inverter AA 550 may be configured to receive the stored power and to provide inverted power to the first meter 171. In an example embodiment, the battery 500 is a lithium ion battery, however, the battery 500 may comprise a capacitor or any suitable energy storage device.

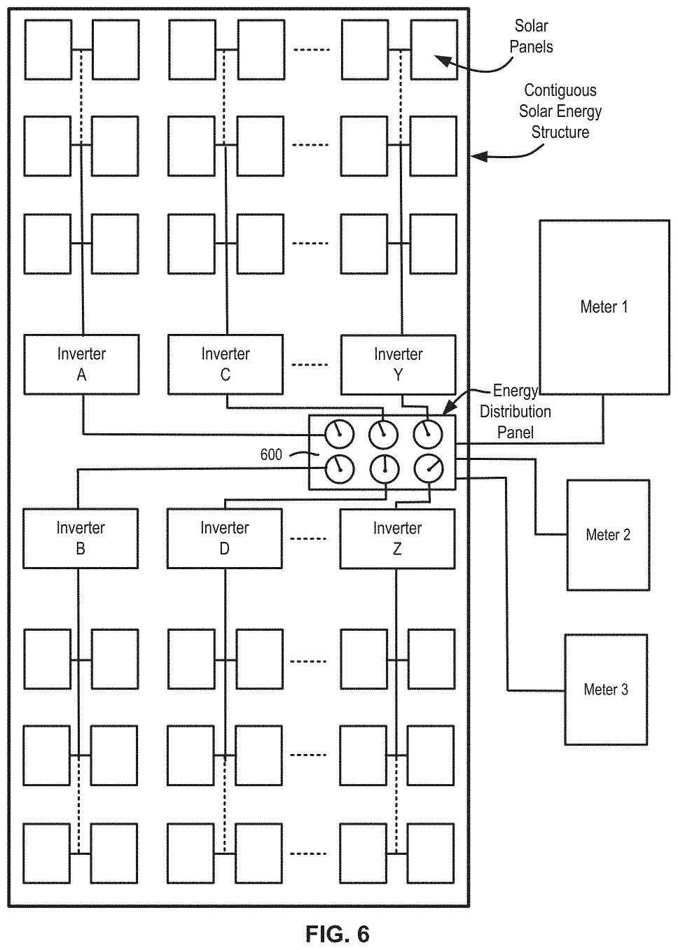

With reference now to FIG. 6, in an example embodiment, the photovoltaic solar energy generation system 100 is configured to re-configurably switch power from subsets of solar panels to specific users. In an example embodiment, the total of the energy generated by all of the solar panels is essentially equal to the total power received by all of the users. In an example embodiment, the photovoltaic solar energy generation system 100 comprises an energy distribution panel 600. The energy distribution panel 600 may be any device that has an input for each inverter, an output for each meter and the means to connect the inputs to the outputs of choice. In an example embodiment, the energy distribution panel 600 is configured to receive energy from at least two inverters of the inverters associated with the photovoltaic solar energy generation system 100. The energy distribution panel 600 is configured to control to which meter the output of each inverter is sent. The energy distribution panel 600 is configured to switch or change the inverter/meter connection as desired. Thus, in an example embodiment, while 100% of the power generated by the solar panels is equal to the total power provided to the users, in an example embodiment where user 1 receives power from inverters A and C, user 2 receives power from inverters Y and Z, and user 3 receives power from inverters B and D, after some period of time, it is possible that user 2 may terminate its lease on the property and stop using power. In that event, the energy distribution panel 600 may reconfigure the power distribution to send power from inverters A, B, and C to user 1 and power from inverters D, Y, and Z to user 3, still totaling 100% of the power generated by the solar panels. Any other redistributions/reconfigurations can be made as appropriate for the situation. This is an advantage in that in a shopping center, when one tenant moves out, another tenant or the utility can take the energy until the new tenant is identified.

### Example Embodiments

In an example embodiment, a method of collecting solar energy comprises: contiguously covering an area with a plurality of photovoltaic solar panels; providing energy from a first inverter associated with a first string of photovoltaic solar panels, from among the plurality of photovoltaic solar panels, to a first meter; and providing energy from a subset of the plurality of solar panels to an electric vehicle charging station as direct current.

In an example embodiment, a method of collecting solar energy comprises: contiguously covering an area with a plurality of photovoltaic solar panels; providing energy from a first inverter associated with a first string of photovoltaic solar panels, from among the plurality of photovoltaic solar panels, to a first meter; and providing energy from a subset of the plurality of solar panels to an energy storage device as direct current.

Notwithstanding the embodiments described above and shown in the accompanying drawing figures, various modifications and inclusions to those embodiments are contemplated and considered within the scope of the present disclosure.

As utilized herein with respect to numerical ranges, the terms “approximately,” “about,” “substantially,” and similar terms generally mean +/−10% of the disclosed values, unless specified otherwise. As utilized herein with respect to structural features (e.g., to describe shape, size, orientation, direction, relative position, etc.), the terms “approximately,” “about,” “substantially,” and similar terms are meant to cover minor variations in structure that may result from, for example, the manufacturing or assembly process and are intended to have a broad meaning in harmony with the common and accepted usage by those of ordinary skill in the art to which the subject matter of this disclosure pertains. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as used herein to describe various embodiments, are intended to indicate that such embodiments are possible examples, representations, or illustrations of possible embodiments (and such terms are not intended to connote that such embodiments are necessarily extraordinary or superlative examples).

References herein to the positions of elements (e.g., “top,” “bottom,” “above,” “below”) are merely used to describe the orientation of various elements in the figures. It should be noted that the orientation of various elements may differ according to other exemplary embodiments, and that such variations are intended to be encompassed by the present disclosure.

As noted above, although the figures and description may illustrate a specific order of method steps, the order of such steps may differ from what is depicted and described, unless specified differently above. Also, two or more steps may be performed concurrently or with partial concurrence, unless specified differently above. Further, one or more steps can be repeated before a next step.

It is important to note that any element disclosed in one embodiment may be incorporated or utilized with any other embodiment disclosed herein. Although only one example of an element from one embodiment that can be incorporated or utilized in another embodiment has been described above, it should be appreciated that other elements of the various embodiments may be incorporated or utilized with any of the other embodiments disclosed herein.

What is claimed is:

1. A solar energy system comprising:
a solar energy structure comprising photovoltaic solar panels contiguously covering an area;
a first inverter configured to receive power from a first string of photovoltaic solar panels, wherein the first inverter is configured to provide the power received at the first inverter to a first meter; and
a second inverter configured to receive power from a second string of photovoltaic solar panels, wherein the second inverter is configured to provide the power received at the second inverter to a second meter.

2. The solar energy system of claim 1, where the solar energy structure covers a parking lot, a rooftop, a building, a gathering place, a RV park or parking place, a semitrailer parking place or loading place, a cool zone for people protection, an agricultural area, park area or an area of ground or water.

3. The solar energy system of claim 1, further comprising:
a third inverter configured to receive power from a third string of photovoltaic solar panels; and
an AC combiner for receiving and combining power from the first inverter and the third inverter; and for providing the combined power received at the AC combiner to the first meter.

4. The solar energy system of claim 3, further comprising a fourth inverter configured to receive power from a fourth string of photovoltaic solar panels, and to provide the power received from the fourth string of photovoltaic solar panels to a third meter.

5. The solar energy system of claim 1, further comprising an electric vehicle charging system, wherein the electric vehicle charging system receives power from a subsection of the plurality of solar panels as direct current.

6. The solar energy system of claim 1, further comprising one or more energy storage devices, wherein the one or more energy storage devices receive power from a subsection of the plurality of solar panels as direct current.

7. A solar energy system comprising:
a solar energy structure comprising photovoltaic solar panels contiguously covering an area and at least two inverters, wherein the at least two inverters include a first inverter and a second inverter;
wherein each of the at least two inverters is configured to respectively route energy to the distribution panel,
and wherein the energy distribution panel is configured to switch the energy from the first inverter to a first meter of the plurality of meters, and to switch the energy from the second inverter to the first meter or to a second meter of the plurality of meters.

8. The system of claim 7, where the solar energy system covers a parking lot, a rooftop, a building, a gathering place, a RV park or parking place, a semitrailer parking place or loading place, a cool zone for people protection, an agricultural area, park area or an area of ground or water.

9. The system of claim 7, further comprising an EV charging station, wherein the EV charging station is configured to receive power from a subsection of the plurality of solar panels as direct current.

10. The system of claim 7, further comprising an energy storage device, wherein the energy storage device is configured to receive power from a subsection of the plurality of solar panels as direct current.

11. A method of collecting solar energy, the method comprising:
contiguously covering an area with a plurality of photovoltaic solar panels;
providing energy from a first inverter associated with a first string of photovoltaic solar panels, from among the plurality of photovoltaic solar panels, to a first meter; and
providing the energy from a different inverter associated with a second string of photovoltaic solar panels, from among the plurality of photovoltaic solar panels and different from the first string of photovoltaic solar panels, to a different meter.

12. The method of claim 11, where the solar energy system covers a parking lot, a rooftop, a gathering place, a RV park or parking place, a semitrailer parking place or loading place, a cool zone for people protection, an agricultural area, park area or an area of ground or water.

13. The method of claim 11, wherein providing energy from the first inverter further comprises receiving energy from the first inverter and a third inverter at an AC combiner, and providing combined power received from the first inverter and the third inverter at the AC combiner to the first meter.

14. The method of claim 11, wherein the relationship between the plurality of strings/inverters of a solar energy generation system to respective meters is: a one-to-one arrangement, a many-to-one arrangement or a many-to-many arrangement.
